(19) United States
(12) Patent Application Publication
(10) Pub. No.: US 2025/0311520 A1
(43) Pub. Date: Oct. 2, 2025

(54) MANUFACTURING METHOD FOR SOLAR CELL, MANUFACTURING APPARATUS FOR SOLAR CELL, PART FOR MANUFACTURE OF SOLAR CELL, AND SOLAR CELL

(71) Applicant: SUMITOMO HEAVY INDUSTRIES, LTD., Tokyo (JP)

(72) Inventor: Hisashi KITAMI, Yokosuka-shi (JP)

(21) Appl. No.: 19/238,353

(22) Filed: Jun. 14, 2025

Related U.S. Application Data
(63) Continuation of application No. PCT/JP2023/044526, filed on Dec. 12, 2023.

(30) Foreign Application Priority Data
Dec. 28, 2022 (JP) 2022-211763

(51) Int. Cl. H10K 30/40; H10F 71/00

(52) U.S. Cl. CPC H10K 30/40; H10F 71/134; H10F 71/138

(57) ABSTRACT

A manufacturing method for a solar cell, which includes a photoelectric conversion layer absorbing light and converting the light into electrical energy, an electrode extracting the electrical energy generated in the photoelectric conversion layer, and a transport layer transporting electrons or holes from the photoelectric conversion layer, includes a transport layer forming step of forming the transport layer, in which in the transport layer forming step, a metal oxide layer is formed by an ion plating method using plasma containing oxygen.

### CROSS-REFERENCE TO RELATED APPLICATIONS

This is a bypass continuation of International PCT Application No. PCT/JP2023/044526, filed on Dec. 12, 2023, which claims priority to Japanese Patent Application No. 2022-211763, filed on Dec. 28, 2022, which are incorporated by reference herein in their entirety.

### BACKGROUND

### Technical Field

Certain embodiments of the present disclosure relate to a manufacturing method for a solar cell, a manufacturing apparatus for a solar cell, a part for the manufacture of a solar cell, and a solar cell.

### Description of Related Art

As disclosed in the related art, a solar cell includes a conductive substrate, an electron transport layer, a photoelectric conversion layer that contains an organic/inorganic perovskite compound, an organic semiconductor layer that serves as a hole transport layer, and an electrode layer. Electrons from the photoelectric conversion layer travel toward the conductive substrate through the electron transport layer, and holes from the photoelectric conversion layer travel toward the electrode layer through the hole transport layer.

### SUMMARY

According to an embodiment of the present disclosure, there is provided a manufacturing method for a solar cell including a photoelectric conversion layer that absorbs light and converts the light into electrical energy, an electrode that extracts the electrical energy generated in the photoelectric conversion layer, and a transport layer that transports electrons or holes from the photoelectric conversion layer. The manufacturing method includes a transport layer forming step of forming the transport layer. In the transport layer forming step, a metal oxide layer is formed by an ion plating method using plasma containing oxygen.

According to another embodiment of the present disclosure, there is provided a manufacturing apparatus for a solar cell including a photoelectric conversion layer that absorbs light and converts the light into electrical energy, an electrode that extracts the electrical energy generated in the photoelectric conversion layer, and a transport layer that transports at least one of electrons and holes from the photoelectric conversion layer. The manufacturing apparatus includes a transport layer forming device for forming the transport layer. The transport layer forming device includes a film forming device that forms a metal oxide layer with an ion plating method using plasma containing oxygen.

According to still another embodiment of the present disclosure, there is provided a part for manufacture of a solar cell used to manufacture a solar cell including a photoelectric conversion layer that absorbs light and converts the light into electrical energy, an electrode that extracts the electrical energy generated in the photoelectric conversion layer, and a transport layer that transports at least one of electrons and holes from the photoelectric conversion layer. The part includes a plasma gun that includes a cathode, a main hearth which includes a main anode and in which a film forming material is disposed, and an auxiliary hearth that includes an auxiliary anode and is provided around the main hearth, in which a metal oxide layer included in the transport layer is formed by an ion plating method using plasma, which contains oxygen and is generated between the plasma gun and the main anode, in a film forming chamber in which the part for manufacture of a solar cell is provided.

According to still another embodiment of the present disclosure, there is provided a solar cell including a photoelectric conversion layer that absorbs light and converts the light into electrical energy, an electrode that extracts the electrical energy generated in the photoelectric conversion layer, and a transport layer that transports at least one of electrons and holes from the photoelectric conversion layer, in which the transport layer includes a metal oxide layer that is formed by an ion plating method using plasma containing oxygen.

### BRIEF DESCRIPTION OF THE DRAWINGS

FIGS. 1A and 1B are schematic diagrams showing examples of a configuration of a solar cell according to an embodiment of the present disclosure.

FIG. 2 is a schematic diagram showing an example of the configuration of the solar cell according to the embodiment of the present disclosure.

FIG. 3 is a schematic diagram showing an example of the configuration of the solar cell according to the embodiment of the present disclosure.

FIG. 4 is a block diagram showing a manufacturing apparatus for a solar cell according to the embodiment of the present disclosure.

FIGS. 5A and 5B are process diagrams showing a manufacturing method for a solar cell according to the embodiment of the present disclosure.

FIG. 6 is a schematic cross-sectional view showing a configuration of a film forming device.

FIG. 7 is a schematic view showing a configuration of a part for the manufacture of a solar cell.

FIG. 8 is a schematic view showing a configuration of a film forming device according to a modification example.

### DETAILED DESCRIPTION

In the above-described solar cell, the electron transport layer and the hole transport layer are often conductive, but often have performance close to insulation properties in order to have band adjustment and charge selectivity and are required to be formed to be thin. Further, it is necessary to suppress the generation of pinholes for the prevention of short circuits. Since a resistance value increases in a case where the electron transport layer or the hole transport layer is too thick, a current value to be extracted decreases. Since a resistance value decreases but pinholes are likely to be generated in a case where the electron transport layer or the hole transport layer is thin, there is a problem that a defect rate increases due to the occurrence of a short circuit. Therefore, there is a demand for improving the productivity while improving the performance of the solar cell.

In the manufacturing method for a solar cell according to the embodiment of the present disclosure, the metal oxide layer is formed by an ion plating method using plasma containing oxygen, in the transport layer forming step of forming the transport layer. Since an electron transport layer or a hole transport layer is formed by an ion plating method which is a film forming method having a high coverage in this way, it is possible to reduce the resistance value of the transport layer and to suppress defects caused by the generation of pinholes. Here, the plasma used for activation in the ion plating method is reactive plasma containing oxygen. Since the reactive plasma containing oxygen is used, it is possible to adjust the amount of oxygen loss from the transport layer during the formation of a film. For this reason, it is possible to suppress the generation of pinholes in the transport layer and to adjust a band within the range of the characteristics of a material. Accordingly, the performance and productivity of the solar cell can be improved.

The plasma may be generated using a pressure gradient type plasma gun, in the transport layer forming step. In a case where the pressure gradient type plasma gun is used, plasma can be stably generated.

The plasma may be guided to a vaporized material using a magnetic field generating unit, in the transport layer forming step. In this case, since plasma can be smoothly guided to the vaporized material, the vaporized material can be caused to react with the plasma, so that productivity can be improved.

For example, the photoelectric conversion layer may contain an organic/inorganic semiconductor having a perovskite structure. Further, the photoelectric conversion layer may contain an organic semiconductor.

The manufacturing method for a solar cell may further include an electrode forming step of forming the electrode on an upper side of a resin substrate, and the transport layer forming step of forming the metal oxide layer on an upper side of the electrode with the ion plating method. In this case, since a film is formed by the ion plating method, it is possible to suppress damage to the resin substrate, which is an organic substance, caused by heat. Accordingly, a resin having low heat resistance can be adopted.

The manufacturing method for a solar cell may further include a first electrode forming step of forming a first electrode on an upper side of a glass substrate, a first transport layer forming step of forming a first transport layer for transporting one of the electrons and the holes on an upper side of the first electrode, a photoelectric conversion layer forming step of forming the photoelectric conversion layer containing an organic substance on an upper side of the first transport layer, a metal oxide layer forming step of forming the metal oxide layer as a second transport layer for transporting the other of the electrons and the holes on an upper side of the photoelectric conversion layer with the ion plating method, and a second electrode forming step of forming a second electrode on an upper side of the metal oxide layer. Since the glass substrate is resistant to heat, a film forming method that is performed at a high temperature can be adopted in the formation of each layer. On the other hand, after the photoelectric conversion layer containing an organic substance susceptible to heat is formed, a film can be formed by an ion plating method to suppress damage to the photoelectric conversion layer, which contains the organic substance, caused by heat.

The manufacturing method for a solar cell may further include a first electrode forming step of forming a first electrode on an upper side of a substrate, a first metal oxide layer forming step of forming a first metal oxide layer as a first transport layer for transporting one of the electrons and the holes on an upper side of the first electrode with the ion plating method, a first organic semiconductor layer forming step of forming a first organic semiconductor layer as the first transport layer on an upper side of the first metal oxide layer with coating, a photoelectric conversion layer forming step of forming the photoelectric conversion layer on an upper side of the first organic semiconductor layer with coating, a second organic semiconductor layer forming step of forming a second organic semiconductor layer as a second transport layer for transporting the other of the electrons and the holes on an upper side of the photoelectric conversion layer with coating, a second metal oxide layer forming step of forming a second metal oxide layer as the second transport layer on an upper side of the second organic semiconductor layer with the ion plating method, and a second electrode forming step of forming a second electrode on an upper side of the second metal oxide layer. In this case, after the first metal oxide layer forming step using the ion plating method is performed, the step of forming each layer with coating is performed until the second metal oxide layer forming step using the ion plating method. The formation of a film using the ion plating method requires a vacuum environment, but the formation of a film using coating does not require a vacuum environment. For this reason, it is possible to smoothly perform coating without creating a vacuum environment in the first organic semiconductor layer forming step, the photoelectric conversion layer forming step, and the second organic semiconductor layer forming step.

According to the manufacturing apparatus for a solar cell, the part for the manufacture of a solar cell, and the solar cell, it is possible to obtain the same actions and effects as those of the above-described manufacturing method for a solar cell.

It is desirable to provide a manufacturing method for a solar cell, a manufacturing apparatus for a solar cell, a part for the manufacture of a solar cell, and a solar cell that can improve performance and productivity.

Hereinafter, a manufacturing method for a solar cell, a manufacturing apparatus for a solar cell, a part for the manufacture of a solar cell, and a solar cell according to an embodiment of the present disclosure will be described with reference to the accompanying drawings. In the description of the drawings, the same elements will be denoted by the same reference numerals and repeated description will be omitted.

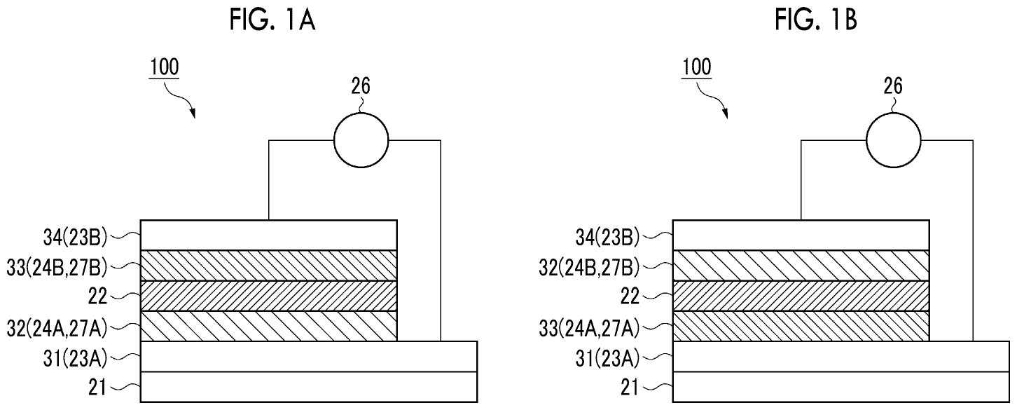

FIGS. 1A and 1B are schematic diagrams showing examples of a configuration of a solar cell 100 according to the present embodiment. As shown in FIGS. 1A and 1B, the solar cell 100 includes a transparent substrate 21, a photoelectric conversion layer 22, a pair of electrodes 23A and 23B, and a pair of transport layers 24A and 24B. The solar cell 100 is a battery that generates power by receiving light.

The transparent substrate 21 is a transparent member that serves as a base for supporting components of the solar cell 100. The photoelectric conversion layer 22 is a layer that absorbs light and converts the light into electrical energy. The electrodes 23A and 23B are layers that extract electrical energy generated by the photoelectric conversion layer 22. The transport layers 24A and 24B are layers that transport electrons or holes from the photoelectric conversion layer 22. The transparent substrate 21, the first electrode 23A, the first transport layer 24A, the photoelectric conversion layer 22, the second transport layer 24B, and the second electrode 23B are laminated in this order in the solar cell 100. A load 26 is connected to the first electrode 23A and the second electrode 23B. The solar cell 100 can supply the generated electrical energy to the load 26. In the following description, in the lamination direction of the solar cell 100, a side corresponding to the transparent substrate 21 is defined as a “lower” side and a side corresponding to the second electrode 23B is defined as an “upper” side. However, the upper and lower sides in the present specification do not limit the posture of the solar cell 100 during use. Meanwhile, in the examples shown in FIGS. 1A and 1B, the lower side on which the transparent substrate 21 is formed may be a light receiving surface or the upper side may be the light receiving surface.

FIG. 1A shows an organic thin film solar cell 100. In the example shown in FIG. 1A, the solar cell 100 includes a transparent conductive layer 31 as the first electrode 23A, a hole transport layer 32 as the first transport layer 24A, an electron transport layer 33 as the second transport layer 24B, and an electrode 34 as the second electrode 23B. In this case, the hole transport layer 32 transports holes from the photoelectric conversion layer 22 to the transparent conductive layer 31. The electron transport layer 33 transports electrons from the photoelectric conversion layer 22 to the electrode 34. In the solar cell 100 shown in FIG. 1A, a side corresponding to the transparent substrate 21 serves as a positive electrode.

FIG. 1B shows a dye-sensitized solar cell 100. In the example shown in FIG. 1B, the solar cell 100 includes a transparent conductive layer 31 as the first electrode 23A, an electron transport layer 33 as the first transport layer 24A, a hole transport layer 32 as the second transport layer 24B, and an electrode 34 as the second electrode 23B. In this case, the hole transport layer 32 transports holes from the photoelectric conversion layer 22 to the electrode 34. The electron transport layer 33 transports electrons from the photoelectric conversion layer 22 to the transparent conductive layer 31. In the solar cell 100 shown in FIG. 1B, a side corresponding to the transparent substrate 21 serves as a negative electrode.

The transport layers 24A and 24B include metal oxide layers 27A and 27B that are formed by an ion plating method using plasma containing oxygen. Both the transport layers 24A and 24B may include the metal oxide layers 27A and 27B (see FIGS. 1A and 1B), or only the first transport layer 24A may include the first metal oxide layer 27A or only the second transport layer 24B may include the second metal oxide layer 27B. In the present embodiment, the hole transport layer 32 and the electron transport layer 33 include metal oxide layers 27A and 27B that are formed by the ion plating method.

The metal oxide layer 27 of the hole transport layer 32 may contain a p-type metal oxide. MoO₃, NiO, V₂O₅, Cu₂O, FeO, CoO, CuAlO₂, CuGaO₂, ZnRh₂O₄, LiNbO₂, or the like is used as the p-type metal oxide. The metal oxide layer 27 of the hole transport layer 32 may contain a dopant that serves as an acceptor for adjusting the number of holes responsible for conduction. Further, the oxidation number of the metal oxide that shows these p-type semiconductor characteristics may be adjusted to adjust conductivity and a band. The metal oxide layer 27 of the electron transport layer 33 may contain an n-type metal oxide. TiO₂, SnO₂, ZnO, AgInO₂, In₂O₃, CdO, SrTiO₃, or the like is used as the n-type metal oxide. The metal oxide layer 27 of the electron transport layer 33 may contain a dopant that serves as a donor for adjusting the number of electrons responsible for conduction. Further, the oxidation number of the metal oxide that shows these n-type semiconductor characteristics may be adjusted to adjust conductivity and a band.

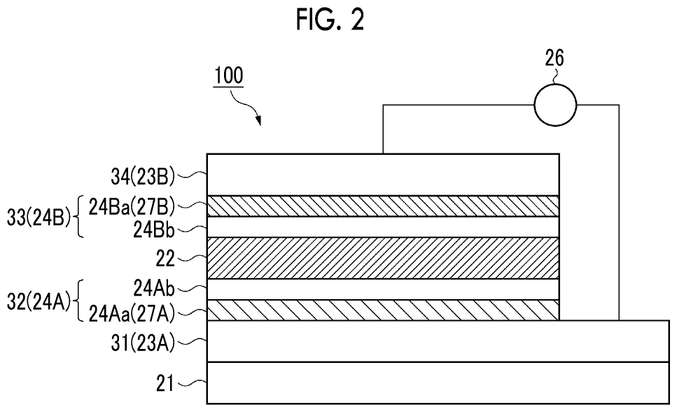

As shown in FIG. 2, each of the transport layers 24A and 24B may have a configuration in which another layer is included in addition to a metal oxide layer 27 formed by an ion plating method and the plurality of layers are laminated. For example, the first transport layer 24A (hole transport layer 32) includes a first layer 24Aa provided on a side facing the electrode 23A (transparent conductive layer 31) and a second layer 24Ab provided on a side facing the photoelectric conversion layer 22. The second transport layer 24B (electron transport layer 33) includes a first layer 24Ba provided on a side facing the electrode 23B (electrode 34) and a second layer 24Bb provided on a side facing the photoelectric conversion layer 22. In an example shown in FIG. 2, the first layers 24Aa and 24Ba include the metal oxide layers 27A and 27B, and the second layers 24Ab and 24Bb include no metal oxide layer. However, layers including the metal oxide layers are not particularly limited in the transport layers 24A and 24B, and the first layers 24Aa and 24Ba may include no metal oxide layer, and the second layers 24Ab and 24Bb may include the metal oxide layers 27A and 27B. Further, the positions of the hole transport layer 32 and the electron transport layer 33 may be interchanged. Furthermore, the number of layers is not particularly limited, and may be three or more. In addition, the number of layers of the hole transport layer 32 and the number of layers of the electron transport layer 33 may be different from each other. Moreover, one of the hole transport layer 32 and the electron transport layer 33 may be formed of a single layer, and the other thereof may be formed of a plurality of layers.

The hole transport layer 32 has a function to allow the passage of holes and to block the passage of electrons. A material of the hole transport layer 32 is adjusted and a material having an energy band where the passage of holes is allowed and the passage of electrons can be blocked is adopted, so that the function is realized. Therefore, it is possible to improve the above-described function by adding the energy band of another layer in addition to the energy band of the metal oxide layer 27. For example, holes are likely to move from the highest occupied molecular orbital (HOMO) or the valence band of the photoelectric conversion layer 22 in a positive direction as viewed from a vacuum level. Accordingly, it is desirable that the level of the HOMO or the valence band of the hole transport layer 32 is positive with respect to the level of the HOMO or the valence band of the photoelectric conversion layer 22. However, the level of the HOMO or the valence band of the hole transport layer 32 is allowed in a case of being negative to such an extent that the transport of holes is not hindered, and is allowed even in a case of being equal to the level of the HOMO or the valence band of the photoelectric conversion layer 22. In a case where a difference in level is too large, transport efficiency is affected. Therefore, the levels of a plurality of hole transport layers 32 are sequentially adjusted stepwise toward the transparent conductive layer 31. On the other hand, electrons are likely to move from the lowest unoccupied molecular orbital (LUMO) or the conduction band of the photoelectric conversion layer 22 in a negative direction as viewed from the vacuum level. Accordingly, in order to block the passage of electrons, it is desirable that the level of the LUMO or the conduction band of the hole transport layer 32 is positive with respect to the level of the LUMO or the conduction band of the photoelectric conversion layer 22. It is preferable that a difference in level is larger, and a larger difference in level prevents electrons from traveling to the transparent conductive layer 31 through the hole transport layer 32. The electron transport layer 33 has a function to allow the passage of electrons and to block the passage of holes. It is also possible to improve the function of the electron transport layer 33 by adding another layer to the metal oxide layer 27. For example, since electrons are likely to move from the LUMO or the conduction band of the photoelectric conversion layer 22 in a negative direction as viewed from the vacuum level, it is desirable that the level of the LUMO or the conduction band of the electron transport layer 33 is negative with respect to the level of the LUMO or the conduction band of the photoelectric conversion layer 22. However, the level of the LUMO or the conduction band of the electron transport layer 33 is allowed in a case of being positive to such an extent that the transport of electrons is not hindered, and is allowed even in a case of being equal to the level of the LUMO or the conduction band of the photoelectric conversion layer 22. In a case where a difference in level is too large, transport efficiency is affected. Therefore, the levels of a plurality of electron transport layers 33 are sequentially adjusted stepwise toward the electrode 34. On the other hand, in order to block the passage of holes, it is desirable that the level of the HOMO or the valence band of the electron transport layer 33 is negative with respect to the level of the HOMO or the valence band of the photoelectric conversion layer 22 so that holes of the HOMO or the valence band of the photoelectric conversion layer 22 are less likely to move. It is preferable that a difference in level is larger, and a larger difference in level prevents holes from traveling to the electrode 34 through the electron transport layer 33.

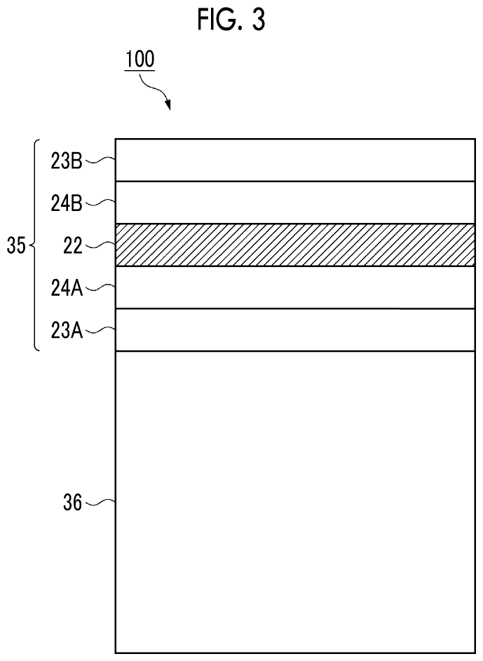

As shown in FIG. 3, a tandem solar cell 100 including a plurality of solar cell modules 35 and 36 may be adopted. The solar cell module 35 includes the first electrode 23A, the first transport layer 24A, the photoelectric conversion layer 22, the second transport layer 24B, and the second electrode 23B described above. The solar cell module 36 is formed of a solar cell of a type different from that of the solar cell module 35. For example, in a case where the solar cell module 35 is formed of a perovskite solar cell, a silicon-based solar cell may be joined to the perovskite solar cell as the solar cell module 36 such that a side corresponding to the perovskite solar cell is a light incident surface. In this case, a transparent conductive film of the silicon-based solar cell may be formed by an ion plating method. The combination of the solar cell modules that form the tandem solar cell is not particularly limited, and the solar cell modules may be selected from organic thin film solar cells, amorphous Si solar cells, polycrystalline Si solar cells, dye-sensitized solar cells, CdTe solar cells, ClGS solar cells, GaAs-based solar cells, HIT-type solar cells, and the like.

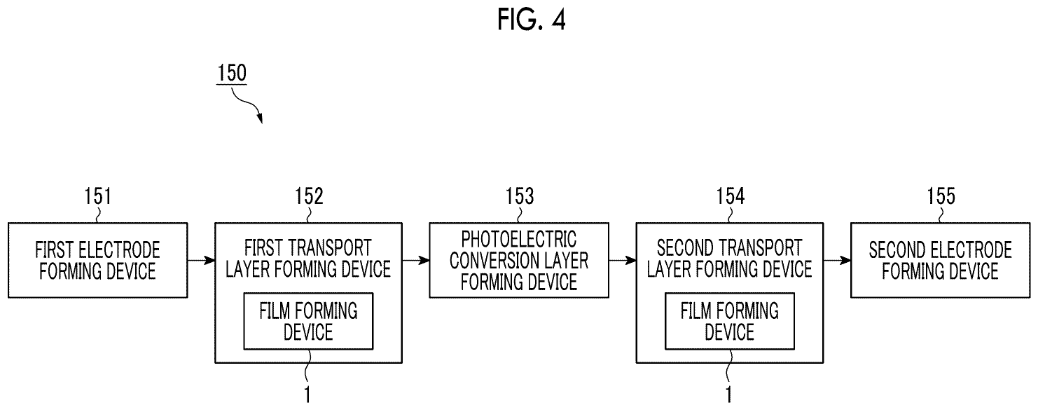

Next, a manufacturing apparatus 150 for manufacturing the solar cell 100 will be described with reference to FIG. 4. FIG. 4 is a block diagram showing a manufacturing apparatus 150 for manufacturing the solar cell shown in FIG. 1A. As shown in FIG. 4, the manufacturing apparatus 150 includes a first electrode forming device 151, a first transport layer forming device 152, a photoelectric conversion layer forming device 153, a second transport layer forming device 154, and a second electrode forming device 155. As described later, various film forming methods, such as a vacuum deposition method, an ion plating method, a sputtering method, a CVD method, a plasma CVD method, a coating method, a spray method, and a sol-gel method, can be adopted as a method of forming each layer. Therefore, unless otherwise specified, it is assumed that each of the devices 151, 152, 153, 154, and 155 includes a device for executing each film forming method. Further, the devices 151, 152, 153, 154, and 155 are connected to each other by a transport mechanism, and a layer is formed by each device while the transparent substrate 21 is transported.

The first electrode forming device 151 is a device that forms the first electrode 23A on the upper side of the transparent substrate 21. In the present specification, an expression of “forms ˜ on the upper side” of the transparent substrate 21 includes not only directly forming the first electrode 23A on the upper surface of the transparent substrate 21, but also forming the first electrode 23A in a state in which another layer is interposed on the upper surface of the transparent substrate 21. The same applies to a case where the expression of “forms ˜ on the upper side” is applied to the other layer. In the examples shown in FIGS. 1A and 1B, the first electrode forming device 151 forms the transparent conductive layer 31.

The first transport layer forming device 152 is a device that forms the first transport layer 24A on the upper side of the first electrode 23A. In a case where the first transport layer 24A is the hole transport layer 32 (see FIG. 1A), the first transport layer forming device 152 includes a device for forming the hole transport layer 32. In a case where the first transport layer 24A is the electron transport layer 33 (see FIG. 1B), the first transport layer forming device 152 includes a device for forming the electron transport layer 33. The first transport layer forming device 152 includes a film forming device 1 for forming the first metal oxide layer 27A that is formed by an ion plating method. Further, in a case where the first transport layer 24A is formed of a plurality of layers as shown in FIG. 2, the first transport layer forming device 152 also includes a device other than the film forming device 1.

The photoelectric conversion layer forming device 153 is a device that forms the photoelectric conversion layer 22 on the upper side of the first transport layer 24A.

The second transport layer forming device 154 is a device that forms the second transport layer 24B on the upper side of the photoelectric conversion layer 22. In a case where the second transport layer 24B is the electron transport layer 33 (see FIG. 1A), the second transport layer forming device 154 includes a device for forming the electron transport layer 33. In a case where the second transport layer 24B is the hole transport layer 32 (see FIG. 1B), the second transport layer forming device 154 includes a device for forming the hole transport layer 32. The second transport layer forming device 154 includes a film forming device 1 for forming the second metal oxide layer 27B that is formed by an ion plating method. Further, in a case where the second transport layer 24B is formed of a plurality of layers as shown in FIG. 2, the second transport layer forming device 154 also includes a device other than the film forming device 1.

The second electrode forming device 155 is a device that forms the second electrode 23B on the upper side of the second transport layer 24B. In the examples of FIGS. 1A and 1B, the second electrode forming device 155 forms the electrode 34.

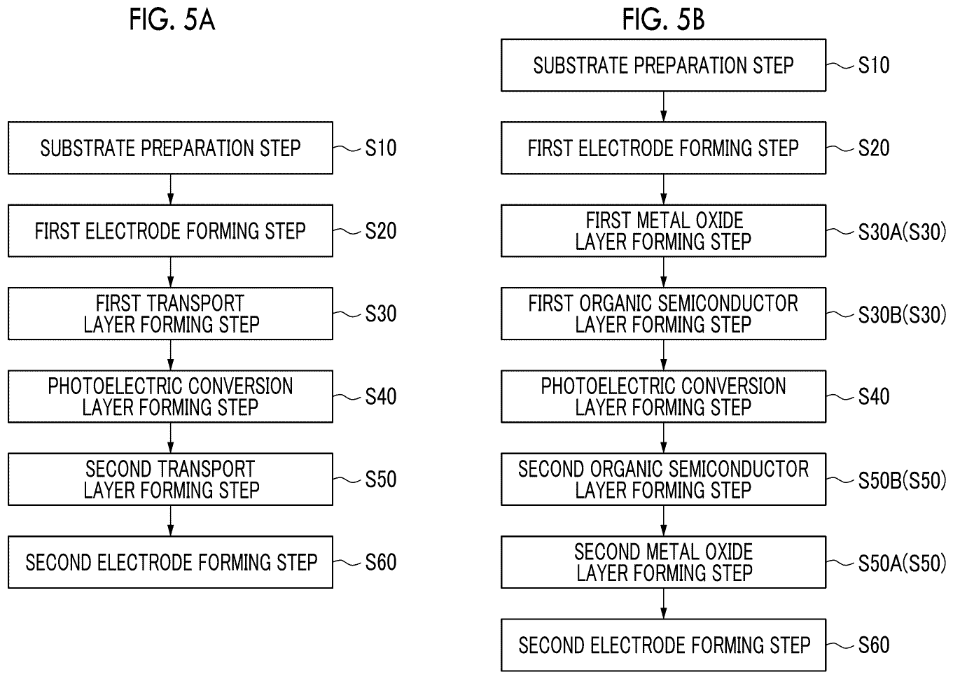

Next, a manufacturing method for the solar cell 100 will be described with reference to FIG. 5A. As shown in FIGS. 5A and 5B, the manufacturing method for the solar cell 100 includes a substrate preparation step S10, a first electrode forming step S20, a first transport layer forming step S30, a photoelectric conversion layer forming step S40, a second transport layer forming step S50, and a second electrode forming step S60.

The substrate preparation step S10 is a step of preparing the transparent substrate 21. The substrate 21 prepared in the substrate preparation step S10 is put into the above-described manufacturing apparatus 150 and is transported so that a film is formed on the substrate 21 by each device.

The first electrode forming step S20 is a step of forming the first electrode 23A on the upper side of the transparent substrate 21. In the examples of FIGS. 1A and 1B, the transparent conductive layer 31 is formed in the first electrode forming step S20.

The first transport layer forming step S30 is a step of forming the first transport layer 24A on the upper side of the first electrode 23A. In a case where the first transport layer 24A is the hole transport layer 32 (see FIG. 1A), the hole transport layer 32 is formed in the first transport layer forming step S30. In a case where the first transport layer 24A is the electron transport layer 33 (see FIG. 1B), the electron transport layer 33 is formed in the first transport layer forming step S30. In the first transport layer forming step S30, the first metal oxide layer 27A is formed by an ion plating method using plasma containing oxygen. Further, in a case where the first transport layer 24A is formed of a plurality of layers as shown in FIG. 2, a layer is also formed by a method other than the ion plating method in the first transport layer forming step S30.

The photoelectric conversion layer forming step S40 is a step of forming the photoelectric conversion layer 22 on the upper side of the first transport layer 24A.

The second transport layer forming step S50 is a step of forming the second transport layer 24B on the upper side of the photoelectric conversion layer 22. In a case where the second transport layer 24B is the electron transport layer 33 (see FIG. 1A), the electron transport layer 33 is formed in the second transport layer forming step S50. In a case where the second transport layer 24B is the hole transport layer 32 (see FIG. 1B), the hole transport layer 32 is formed in the second transport layer forming step S50. In the second transport layer forming step S50, the second metal oxide layer 27B is formed by an ion plating method using plasma containing oxygen. Further, in a case where the second transport layer 24B is formed of a plurality of layers as shown in FIG. 2, a layer is also formed by a method other than the ion plating method in the second transport layer forming step S50.

The second electrode forming step S60 is a step of forming the second electrode 23B on the upper side of the second transport layer 24B. In the examples of FIGS. 1A and 1B, the electrode 34 is formed in the second electrode forming step S60.

Next, a method of forming each layer in each step, the configuration of each layer, and the like will be described in detail. Here, the solar cell 100 in which a side corresponding to the transparent substrate 21 serves as a negative electrode as shown in FIG. 1B will be described as an example.

### Transparent Substrate

A glass substrate, a resin substrate, or the like is used as the transparent substrate 21. Soda lime glass, non-alkali glass, or the like may be used as glass. Quartz glass can also be adopted. However, since quartz glass is expensive, other glasses are preferable. Polyethylene terephthalate (PET), polycarbonate (PC), cycloolefin polymer (COP), or the like may be used as a resin. Polyimide (PI) can also be adopted. However, since PI is expensive, other resins are preferable.

In a case where a resin substrate is used as the transparent substrate 21, gas barrier properties, such as O₂ permeability and H₂O permeability, become an issue. For this reason, a gas barrier film is usually formed. SiO₂, Al₂O₃, SiN, SiON, or the like is adopted for the gas barrier film, and the gas barrier film is formed by a vacuum deposition method, an ion plating method, a sputtering method, a CVD method, a plasma CVD method, or the like. The gas barrier film may be formed between the transparent substrate 21 and the transparent conductive layer 31, may be formed on the outside which is a light incident surface, or may be formed in the final step.

The thickness of the transparent substrate 21 is not particularly limited, and may be 10 μm or less, 100 μm or less, 0.7 mm or more, or 2.2 mm or more. As the transparent substrate 21, a resin that is thin and bendable may be adopted, a thick glass may be adopted, or substrates having various thicknesses may be adopted. In a case where a resin is adopted, it is necessary to use a resin that has a thickness allowing the resin to be bent and to pay attention to moisture permeability or the like. For this reason, a barrier film is required.

### Transparent Conductive Layer

A film may be formed on the transparent substrate 21 using a fluorine-doped tin oxide (FTO), a tin-doped indium oxide (ITO), a tungsten-doped indium oxide (IWO), a cerium-doped indium oxide (ICO), an indium gallium zinc oxide (IGZO), a gallium-doped zinc oxide (GZO), an aluminum-doped zinc oxide (AZO), or the like by a vacuum deposition method, an ion plating method, a sputtering method, a CVD method, a plasma CVD method, a coating method, a spray method, or the like to form the transparent conductive layer 31. A transparent conductive layer 31 made of ITO, FTO, GZO, IGZO, or the like in which a dopant is added to In₂O₃, SnO₂, ZnO, or the like may be formed. The dopant is not particularly limited, and examples of the dopant include Sn, W, Ce, Al, and Ga.

The thickness of the transparent conductive layer 31 is not particularly limited, and may be 50 nm or less, 100 nm or less, 100 nm or more, or 150 nm or more. It is more preferable to take a film thickness that is subjected to optical matching to optimize the incidence of light on the photoelectric conversion layer.

### Electron Transport Layer

The electron transport layer 33 is provided on the transparent conductive layer 31, so that photoelectric conversion efficiency can be improved. An n-type organic semiconductor polymer, an n-type organic semiconductor monomer, an n-type metal oxide, an alkali metal halide, or the like may be used as the material of the electron transport layer 33. In a case where these are formed on the transparent conductive layer 31, the transparent conductive layer 31 operates as a negative electrode.

A boron-containing polymer, poly(benzobisimidazobenzophenanthroline), or the like is used as the n-type organic semiconductor polymer, and the n-type organic semiconductor polymer is dissolved in an organic solvent to form a film with a coating method (screen printing, a spin coating method, or the like) and the organic solvent is then removed by heat treatment or the like in many cases. Generally, since an organic semiconductor polymer exhibiting n-type characteristics has mobility lower than the mobility of a p-type organic semiconductor, the following materials are often used.

Fullerene, a fullerene derivative (for example, PCBM or the like) in which a functional group is introduced into fullerene, or the like may be used as the n-type organic semiconductor monomer. Fullerene is often formed as a film by vacuum deposition. Since a fullerene derivative is dissolved in an organic solvent due to a functional group, the fullerene derivative is often formed as a film by a coating method. Fullerene can also be formed as a film by vacuum deposition.

The material of the n-type metal oxide is as described above. The above-described film forming method for the metal oxide layer 27A is an ion plating method. However, in a case where another metal oxide layer is formed in addition to the metal oxide layer 27A, a wide variety of methods from a dry process to a coating method, such as a vacuum deposition method, a sputtering method, a CVD method, a plasma CVD method, a sol-gel method, and a spray method may be adopted as another film forming method. In the case of a coating method, a solution in which a precursor is dissolved in a solvent may be applied and may then be sintered by heat treatment, plasma treatment, microwave heating treatment, or the like to form a film. Since heat treatment is generally performed at a temperature of about 200° C. to 500° C., the substrate is required to have heat resistance. For this reason, a glass substrate is often used.

LiF is often used mainly as the alkali metal halide, and is formed as a film by vacuum deposition or the like. The electron transport layer 33 may be formed of a plurality of layers to improve electron extraction efficiency. For example, fullerene may be formed on a side corresponding to a perovskite layer, which is the photoelectric conversion layer 22, TiO₂ may be formed on a side corresponding to the transparent conductive layer 31, and LiF may further be formed between TiO₂ and the transparent conductive layer 31. The electron transport layer made of an n-type organic semiconductor polymer, an n-type organic semiconductor monomer, an n-type metal oxide, or an alkali metal halide, and an n-type metal oxide formed by a film forming method other than an ion plating method are adopted as the layers of the electron transport layer 33 other than the metal oxide layer 27A formed by an ion plating method. Alternatively, in a case where the hole transport layer 32 includes the metal oxide layer 27B formed by an ion plating method, the electron transport layer 33 does not need to include the metal oxide layer 27A formed by an ion plating method. Accordingly, in this case, the electron transport layer made of an n-type organic semiconductor polymer, an n-type organic semiconductor monomer, an n-type metal oxide, or an alkali metal halide and an n-type metal oxide formed by a film forming method other than an ion plating method may be adopted even in a case where the electron transport layer 33 is formed of a single layer.

The thickness of the electron transport layer 33 is not particularly limited, and may be 10 nm or less, 50 nm or less, 100 nm or more, or 150 nm or more. Further, it is preferable that the electron transport layer 33 is pinhole-free. The term “pinhole-free” means a state in which a film is not short-circuited electrically and chemically in a film thickness direction. In a pinhole-free state, there is no pinhole having a size that causes the photoelectric conversion layer 22 and the transparent conductive layer 31 to be short-circuited in the above-described range of the thickness.

### Photoelectric Conversion Layer

In a perovskite solar cell, a halide-based organic/inorganic perovskite semiconductor (for example, CH₃NH₃PbI₃) having a perovskite structure, which is a crystal structure represented by a general formula “ABX₃”, may be used as the photoelectric conversion layer 22. In an organic thin film solar cell, a bulk heterojunction layer in which an n-type organic semiconductor (for example, PCBM) and a p-type organic semiconductor (for example, P3HT) are mixed with each other may be used.

In the case of a perovskite solar cell, A in the general formula “ABX₃” is a cation, and methylammonium ions (CH₃NH₃⁺) that are organic molecules represented by CₗNₘHₙ (l, m, and n are positive integers), formamidinium (CH(NH₂)₂⁺), inorganic substances, such as Cs⁺, K⁺, and Rb⁺, and the like may be used. B in the general formula “ABX₃” is a cation, and Pb²⁺, Sn²⁺, Ge²⁺, Mg²⁺, Ca²⁺, Sr²⁺, Ba²⁺, Cu²⁺, Fe²⁺, Pd²⁺, Eu²⁺, Bi³⁺, Sb³⁺, and the like may be used. X in the general formula “ABX₃” is an anion, and I⁻, Br⁻, Cl⁻, F⁻, and the like may be used. Since a band gap of the perovskite layer is changed in a case where the cations and the anions are combined, the degree of light absorption can be adjusted. For this reason, various combinations can be considered depending on a single solar cell, a tandem solar cell, an outdoor solar cell, and an indoor solar cell, and a configuration in which each of A, B, and X in the general formula “ABX₃” is made up of a mixture of a plurality of types may be adopted. A vacuum deposition method, a coating method, or the like may be used as a method of forming the perovskite layer. CH₃NH₃PbI₃(MAPbI) will be described as an example. In the case of vacuum deposition, there are a co-deposition method in which CH₃NH₃I=MAI and PbI₂ are flown from respective deposition sources to form a MAPbI film on a substrate, a two-stage deposition method in which PbI₂ is deposited on a substrate and MAI is then deposited on PbI₂ to form a MAPbI film, and the like. In the case of a coating method, there are a one-liquid method in which one solution in which MAI and PbI₂ are mixed in advance is used, a two-liquid method in which a PbI₂ film formed using a PbI₂ solution is coated with an MAI solution, an immersion method in which a PbI₂ film is immersed in a MAI solution, and the like.

A one-liquid method will be described as an example. MAI and PbI₂ are dissolved in an organic solvent, such as dimethylformamide (DMF) or dimethyl sulfoxide (DMSO), at a desired ratio (for example, 1:1) to prepare a solution. The solution is applied by a spin coating method or the like to form a film on a transparent conductive substrate on which the electron transport layer 33 is formed. Toluene in which the perovskite layer is hardly dissolved is dropped during the spin coating to form an intermediate complex, such as MA₂Pb₃I₈·2DMSO. The coated substrate is heated to about 100° C., so that a MAPbI film as a perovskite layer is formed.

In the case of an organic thin film solar cell, fullerene or a fullerene derivative may be used as an n-type organic semiconductor and a monomer, such as metal phthalocyanine, or a polymer, such as poly(3-hexylthiophene-2,5-diyl) (P3HT) having a thiophene skeleton, may be used as a p-type organic semiconductor. Fullerene, metal phthalocyanine, and the like are formed as a film by vacuum deposition, and a fullerene derivative, P3HT, and the like are formed as a film by a coating method in many cases. A bulk heterojunction layer, which forms a photoelectric conversion layer by being formed while being mixed during vacuum deposition or during coating, is formed.

In the case of a coating method, P3HT and PCBM are dissolved in an organic solvent, such as chloroform, to prepare a mixed solution. The solution is applied to a transparent conductive substrate on which an electron transport layer is formed to form the bulk heterojunction layer.

The thickness of the photoelectric conversion layer 22 is not particularly limited, and may be 100 nm or less, 200 nm or less, 300 nm or more, or 500 nm or more.

### Hole Transport Layer

The hole transport layer 32 is formed on the photoelectric conversion layer 22, so that photoelectric conversion efficiency can be improved. A p-type organic semiconductor monomer, a p-type organic semiconductor polymer, a p-type metal oxide, and the like may be used as the hole transport layer 32.

Metal phthalocyanine, spiro-OMeTAD (2,2′,7,7′-tetrakis[N,N-di-P-methoxyphenylamine]-9,9′-spirobifluorene), and the like may be used as the p-type organic semiconductor monomer. The hole transport layer 32 may be formed by vacuum deposition or a coating method.

Poly[bis(4-phenyl)(2,4,6-trimethylphenyl)amine] (PTAA), P3HT, PEDOT:PSS(poly(3,4-ethylenedioxythiophene)-poly(styrenesulfonate)) and the like may be used as the p-type organic semiconductor polymer. These may be formed by a coating method.

In a case where a p-type organic semiconductor layer is formed by a coating method, it is desirable to prepare a solution using a solvent in which MAPbI as a perovskite layer, P3HT:PCBM as a bulk heterojunction layer, or the like is hardly dissolved.

The material of the p-type metal oxide is as described above. The above-described film forming method for the metal oxide layer 27B is an ion plating method. However, in a case where another metal oxide layer is formed in addition to the metal oxide layer 27B, a vacuum deposition method, a sputtering method, a CVD method, a plasma CVD method, an ALD method, and the like may be used as another film forming method. It is desirable to form a film at a low temperature so that the photoelectric conversion layer is not broken by input heat during a dry process.

The hole transport layer 32 may have a structure in which a plurality of materials are laminated. For example, a p-type semiconductor having hole selectivity, such as CuO, or an insulator may be laminated. A p-type organic semiconductor monomer, the hole transport layer 32 made of a p-type organic semiconductor polymer, and a p-type metal oxide formed by a film forming method other than an ion plating method are adopted as the layers of the hole transport layer 32 other than the metal oxide layer 27B formed by an ion plating method. Alternatively, in a case where the electron transport layer 33 includes the metal oxide layer 27A formed by an ion plating method, the hole transport layer 32 does not need to include the metal oxide layer 27B formed by an ion plating method. Accordingly, in this case, a p-type organic semiconductor monomer, the hole transport layer 32 made of a p-type organic semiconductor polymer, and a p-type metal oxide formed by a film forming method other than an ion plating method may be adopted even in a case where the hole transport layer 32 is formed of a single layer.

The thickness of the hole transport layer 32 is not particularly limited, and may be 10 nm or less, 50 nm or less, 100 nm or more, or 150 nm or more. Further, it is preferable that the electron transport layer 33 is pinhole-free. The term “pinhole-free” means a state in which a film is not short-circuited electrically and chemically in a film thickness direction. In a pinhole-free state, there is no pinhole having a size that causes the photoelectric conversion layer 22 and the electrode 34 to be short-circuited in the above-described range of the thickness.

### Electrode

A transparent conductive layer or metal is formed on the hole transport layer as the electrode 34. Silver or gold may be used as the metal. A coating method using a silver paste or the like, a vacuum deposition method, an ion plating method, a sputtering method, or the like may be used for the formation of the metal. The formation of the transparent conductive layer is as shown in Transparent conductive layer, and is often performed by a dry process. Metal is often formed on the transparent conductive layer as a collector electrode.

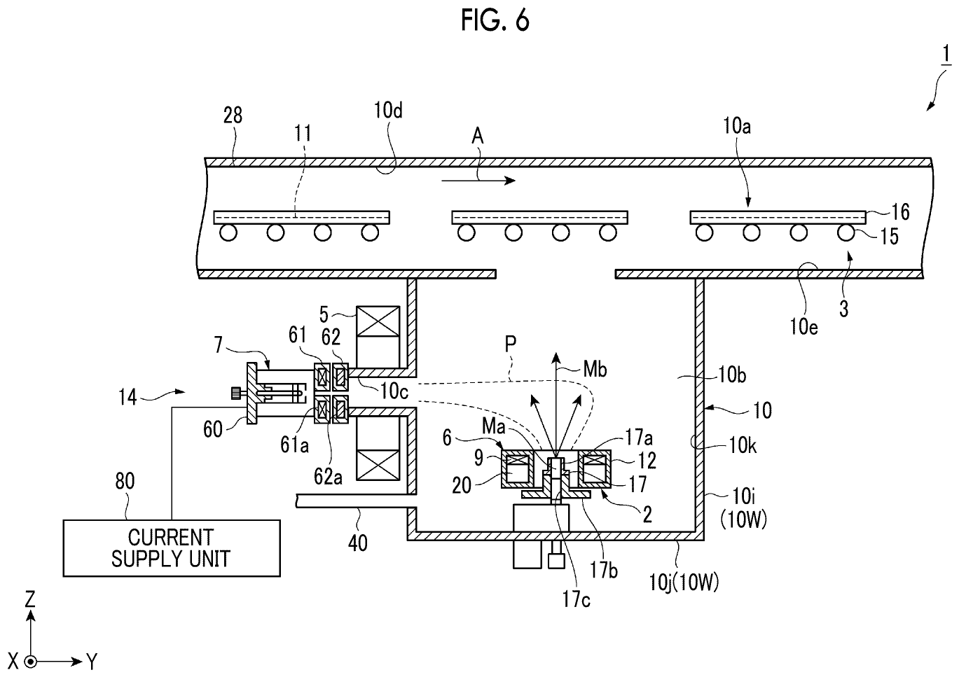

Next, a specific example of the film forming device 1 will be described with reference to FIG. 6. The film forming device 1 is a device that forms the metal oxide layer 27 with an ion plating method using plasma containing oxygen. FIG. 6 is a schematic cross-sectional view showing a configuration of the film forming device 1. The film forming device 1 according to the examples shown in FIGS. 1A and 1B is a reactive plasma deposition (RPD) film forming device used in RPD that is a type of a so-called ion plating method. A feature of the RPD is that plasma generated at a high density using a pressure gradient type plasma gun 7 is introduced into a film forming material Ma by a hearth mechanism 2 to perform the sublimation of the material and the ionization of sublimated material particles with the same mechanism. Since high-density plasma is used in RPD, the ionization rate of the material particles is high and a thin film having high density and strong adhesion to a substrate can be formed as compared to a general ion plating method. For convenience of description, an XYZ coordinate system is shown in FIG. 6. A Y-axis direction is a direction in which an object to be described later is transported. A Z-axis direction is a direction in which the object and a hearth mechanism to be described later face each other. An X-axis direction is a direction perpendicular to the Y-axis direction and the Z-axis direction.

The film forming device 1 may be a so-called horizontal film forming device in which an object 11 is disposed and transported in a vacuum chamber 10 such that a plate thickness direction of the object 11 is substantially a vertical direction. In this case, the X-axis direction and the Y-axis direction are horizontal directions and the Z-axis direction is a vertical direction and the plate thickness direction. The film forming device 1 may be a so-called vertical film forming device in which the object 11 is disposed and transported in a vacuum chamber 10 in a state of being inclined from a state in which the object 11 is upright or stands upright such that a plate thickness direction of the object 11 is a horizontal direction (the Z-axis direction in FIG. 6). In this case, the Z-axis direction is the horizontal direction and the plate thickness direction of the object 11, the Y-axis direction is the horizontal direction, and the X-axis direction is the vertical direction. A film forming device according to an embodiment of the present disclosure will be described below with reference to a horizontal film forming device as an example.

The film forming device 1 includes a vacuum chamber 10, a transport mechanism 3, and a film forming mechanism 14.

The vacuum chamber 10 is a member in which the object 11 is accommodated and film forming treatment is performed. The vacuum chamber 10 includes a transport chamber 10a in which the object 11 on which a film made of the film forming material Ma is to be formed is transported, a film forming chamber 10b in which the film forming material Ma is diffused, and a plasma port 10c through which plasma P emitted in the form of a beam from a pressure gradient type plasma gun 7 is received to the vacuum chamber 10. The transport chamber 10a, the film forming chamber 10b, and the plasma port 10c communicate with each other. The transport chamber 10a is set in a predetermined transport direction (an arrow A in FIG. 6) (in the Y-axis). Further, the vacuum chamber 10 is made of a conductive material and is connected to a ground potential.

The film forming chamber 10b includes a pair of side walls that is disposed along the transport direction (arrow A), a pair of side walls 10h and 10i that is disposed along a direction (Z-axis direction) intersecting the transport direction (arrow A), and a bottom wall 10j that is disposed to intersect the X-axis direction, as wall portions 10W.

The transport mechanism 3 transports substrate holding members 16, which hold objects 11 in a state of facing the film forming material Ma, in the transport direction (arrow A). For example, the substrate holding member 16 is a frame body that holds an outer peripheral edge of the object 11. The transport mechanism 3 includes a plurality of transport rollers 15 installed in the transport chamber 10a. The transport rollers 15 are arranged at regular intervals in the transport direction (arrow A), and transport the substrate holding members 16 in the transport direction (arrow A) while supporting the substrate holding members 16. In the case of the film forming device 1 of the first transport layer forming device 152, the object 11 is a substrate that includes the transparent substrate 21 and the first electrode 23A. In the case of the film forming device 1 of the second transport layer forming device 154, the object 11 is a substrate that includes the transparent substrate 21, the first electrode 23A, the first transport layer 24A, and the photoelectric conversion layer 22.

Subsequently, the configuration of the film forming mechanism 14 will be described in detail. The film forming mechanism 14 causes particles, which are generated as a result of the sublimation of the film forming material Ma, to adhere to the object 11 using the ion plating method. The film forming mechanism 14 includes a plasma gun 7, a steering coil 5, a hearth mechanism 2, and a ring hearth 6.

The plasma gun 7 is, for example, a pressure gradient type plasma gun, and a main body portion of the plasma gun 7 is connected to the film forming chamber 10b via the plasma port 10c provided in the side wall of the film forming chamber 10b. The plasma gun 7 generates plasma P in the vacuum chamber 10. The plasma P generated by the plasma gun 7 is emitted from the plasma port 10c into the film forming chamber 10b in the form of a beam. Accordingly, the plasma P is generated in the film forming chamber 10b.

The plasma gun 7 discharges electricity to introduced argon gas through a cathode 60 to generate plasma. A first intermediate electrode (grid) 61 and a second intermediate electrode (grid) 62 are concentrically disposed between the cathode 60 and the plasma port 10c. An annular permanent magnet 61a for converging the plasma P is built in the first intermediate electrode 61. An electromagnetic coil 62a is also built in the second intermediate electrode 62 to converge the plasma P.

The steering coil 5 is provided around the plasma port 10c on which the plasma gun is mounted. The steering coil 5 guides the plasma P into the film forming chamber 10b. The steering coil 5 is excited in a case where current is caused to flow through the steering coil 5 by a power source (not shown) for the steering coil.

The hearth mechanism 2 holds the film forming material Ma. The hearth mechanism 2 is provided in the film forming chamber 10b of the vacuum chamber 10 and is disposed on a negative side in the Z-axis direction as viewed from the transport mechanism 3. The hearth mechanism 2 includes a main hearth 17 that is a main anode which guides the plasma P emitted from the plasma gun 7 to the film forming material Ma or a main anode to which the plasma P emitted from the plasma gun 7 is guided. The configuration of the main hearth will be described later.

The ring hearth 6 (magnetic field generating unit) is an auxiliary anode that includes an electromagnet for inducing the plasma P. The ring hearth 6 is disposed around a container 17a of the main hearth 17 that holds the film forming material Ma. The ring hearth 6 includes an annular coil 9, an annular permanent magnet part 20, and an annular container 12, and the coil 9 and the permanent magnet part 20 are accommodated in the container 12. In the present embodiment, the coil 9 and the permanent magnet part 20 are installed in this order on the negative side in the Z-axis direction as viewed from the transport mechanism 3. However, the permanent magnet part 20 and the coil 9 may be installed in this order on the negative side in the Z-axis direction. The ring hearth 6 generates a cusp magnetic field that controls the direction of the plasma P to be incident on the film forming material Ma or the direction of the plasma P to be incident on the main hearth 17 according to the magnitude of current flowing through the coil 9.

A gas supply unit 40 supplies carrier gas and oxygen gas into the vacuum chamber 10. For example, rare gases such as argon and helium are adopted as substances contained in the carrier gas. The gas supply unit 40 is disposed outside the vacuum chamber 10, and supplies raw material gas into the vacuum chamber 10 through a gas supply port provided in the side wall (for example, the side wall 10h) of the film forming chamber 10b. The gas supply unit 40 supplies carrier gas and oxygen gas of which the flow rates are based on a control signal transmitted from a control unit. Further, the gas supply unit 40 may supply water. The amount of moisture in the vacuum chamber is controlled to any partial pressure to adjust the quality of a film to be formed.

A current supply unit 80 supplies current to the plasma gun 7. Accordingly, the plasma gun 7 discharges electricity with discharge current having a predetermined value. The current supply unit 80 supplies current of which the current value is based on a control signal transmitted from the control unit.

The main hearth 17 functions as a sublimation unit that sublimates the film forming material Ma. The main hearth 17 includes a tubular container 17a that is filled with the film forming material Ma and extends toward a positive side in the Z-axis direction, and a flange portion 17b that protrudes from the container 17a. The main hearth 17 is maintained at a positive potential with respect to a ground potential of the vacuum chamber 10. Therefore, the main hearth 17 serves as an electrode (anode) in the discharge of electricity and can attract the plasma P. A through-hole 17c that is used to fill the container 17a with film forming material Ma is formed in the container 17a of the main hearth 17 on which the plasma P is incident. Further, a tip portion of the film forming material Ma is exposed to the film forming chamber 10b at one end of the through-hole 17c.

The material of the transport layers 24A and 24B is adopted as the film forming material Ma. In a case where the film forming material Ma is made of a conductive material and the main hearth 17 is irradiated with the plasma P, the plasma P is directly incident on the film forming material Ma, the tip portion of the film forming material Ma is heated and sublimated, and film forming material particles Mb (vaporized material) ionized by the plasma P, which is reactive plasma containing oxygen gas, are diffused in the film forming chamber 10b. The film forming material particles Mb diffused in the film forming chamber 10b are ionized by the plasma P, are moved toward the positive side in the Z-axis direction in the film forming chamber 10b, and adhere to the surface of the object 11 in the transport chamber 10a. The film forming material Ma is a solid material that is formed in a columnar shape to have a predetermined length, and the hearth mechanism 2 is filled with a plurality of the film forming materials Ma at a time. Then, the film forming material Ma is sequentially pushed out from the negative side of the hearth mechanism 2 in the Z-axis direction in accordance with the sublimation of the film forming material Ma such that the tip portion of the film forming material Ma positioned on a leading end side maintains a predetermined positional relationship with an upper end of the main hearth 17 to make an atomic composition constant in the film thickness direction. In a case where the film forming material Ma is an insulating material, the plasma P is incident into the main hearth 17. Accordingly, the main hearth 17 is heated, so that the film forming material Ma is heated and sublimated.

In the above-described embodiment, the film forming device using RPD among ion plating methods is superior to a general ion plating method in terms of the following respects. Since the pressure gradient type plasma gun 7 is used in the film forming device using RPD, the sublimation rate of the film forming material is high due to DC arc discharge of large current and plasma can be generated at a high density. Therefore, the ionization rate of the film forming material particles is high and the transport layer can be formed quickly as compared to general ion plating. From this point of view, the film forming device using RPD contributes to the acceleration of the manufacturing of a solar cell. Further, in a case where the ring hearth 6 is provided or a plurality of pressure gradient type plasma guns 7 are arranged in the film forming device using RPD, a transport layer having high quality can be formed over a wide range as compared to general ion plating. From this point of view, the film forming device using RPD contributes to the manufacture of large-area solar cells.

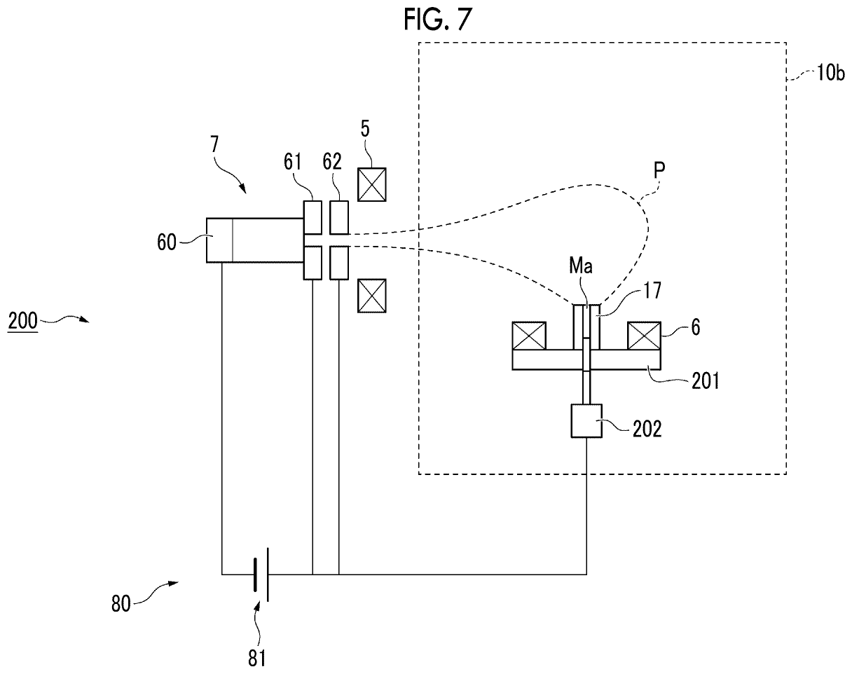

A part 200 for the manufacture of a solar cell according to the present embodiment will be described with reference to FIG. 7. As shown in FIG. 7, the part 200 for the manufacture of a solar cell includes at least the plasma gun 7, the main hearth 17, and the ring hearth 6 (auxiliary hearth). The plasma gun 7 includes the cathode 60, the first intermediate electrode 61, and the second intermediate electrode 62. The main hearth 17 is a member which includes the main anode and in which the film forming material Ma can be disposed. The ring hearth 6 is a member that includes an auxiliary anode and is provided around the main hearth 17. The part 200 for the manufacture of a solar cell can form the metal oxide layers 27A and 27B included in the transport layers 24A and 24B using an ion plating method that uses plasma containing oxygen and generated between the plasma gun 7 and the main hearth 17 (main anode) in the film forming chamber 10b in which the part 200 for the manufacture of a solar cell is provided. The part 200 for the manufacture of a solar cell further includes the steering coil 5 and the current supply unit 80. The current supply unit 80 includes a main power source 81 and an auxiliary power source. Further, the main hearth 17 and the ring hearth 6 are placed on a main hearth base 201. Furthermore, the film forming material Ma is supplied to the main hearth 17 by a material supply unit 202. In addition, the same components of the part 200 for the manufacture of a solar cell as the components of the film forming device 1 shown in FIG. 6 have the same configuration as described above.

The film forming device applied in the present disclosure is not limited to the above-described embodiment of the RPD film forming device, and can be applied to ion plating methods in general. A method of vaporizing the film forming material and a method of generating plasma may be present as separate mechanisms. For example, the ring hearth may be omitted, and plasma may be generated by a method other than the pressure gradient type plasma gun. For example, a film forming device that sublimates a film forming material using a resistance heating device or an electron gun, and forms a film using plasma generated by an RF coil may be adopted.

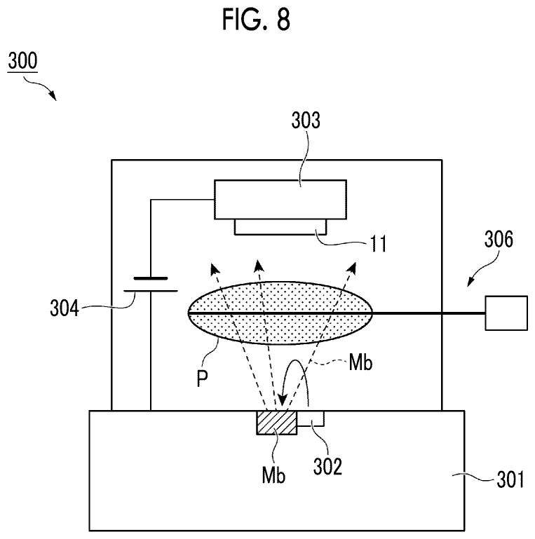

For example, a film forming device 300 using a general ion plating method may be adopted as shown in FIG. 8. The film forming device 300 includes a base part 301, an electron gun 302, a support part 303, a power source 304, and a plasma generating unit 306. The base part 301 supports film forming material particles Mb and supports the electron gun 302. The base part 301 faces an object 11 supported by the support part 303 in a state of being separated from the object 11. The electron gun 302 irradiates a film forming material Ma with particle beams. Accordingly, the film forming material Ma is vaporized, and vaporized film forming material particles Mb fly toward the object 11 and adhere to the object 11. The plasma generating unit 306 generates plasma P between the base part 301 and the object 11 using a high-frequency power source. Accordingly, the film forming material particles Mb are charged. A voltage is applied to the object 11 by the power source 304 via the support part 303. Therefore, the film forming material particles Mb flying in are attracted to the object 11 and are deposited on the object 11.

For example, a resin substrate may be adopted as the transparent substrate 21, ITO may be adopted as the transparent conductive layer 31, and TiO₂ may be adopted as the first metal oxide layer 27A of the electron transport layer 33 formed by an ion plating method. The film forming material Ma used to form the metal oxide layer 27A is not particularly limited as long as the film forming material Ma contains Ti. In this case, the transparent substrate 21 formed of a resin substrate is prepared in the substrate preparation step S10 shown in FIG. 5A. In the first electrode forming step S20, the transparent conductive layer 31 made of ITO is formed on the upper side of the resin substrate. In the first transport layer forming step S30, the first metal oxide layer 27A is formed on the upper side of the transparent conductive layer 31 by an ion plating method. The materials of the other layers are not particularly limited.

For example, a glass substrate may be adopted as the transparent substrate 21, ITO may be adopted as the transparent conductive layer 31, NiO formed by a sputtering method may be adopted as the hole transport layer 32, a perovskite layer containing an organic substance may be adopted as the photoelectric conversion layer 22, SnO₂ may be adopted as the second metal oxide layer 27B of the electron transport layer 33 formed by an ion plating method, and an electrode 34 made of metal may be adopted.

In this case, the transparent substrate 21 formed of a glass substrate is prepared in the substrate preparation step S10 shown in FIG. 5A. In the first electrode forming step S20, the transparent conductive layer 31 made of ITO is formed on the upper side of the glass substrate. In the first transport layer forming step S30, the hole transport layer 32 made of NiO is formed on the upper side of the transparent conductive layer 31 by a sputtering method. In the photoelectric conversion layer forming step S40, the photoelectric conversion layer 22 formed of a perovskite layer containing an organic substance is formed on the upper side of the hole transport layer 32. In the second transport layer forming step S50 (metal oxide layer forming step), SnO₂ as the second metal oxide layer 27B formed by an ion plating method is formed on the upper side of the photoelectric conversion layer 22 as the electron transport layer 33. In the second electrode forming step S60, the electrode 34 made of metal is formed on the upper side of the second metal oxide layer 27B.

For example, a manufacturing method shown in FIG. 5B may be adopted. In FIG. 5B, the first transport layer forming step S30 includes a first metal oxide layer forming step S30A and a first organic semiconductor layer forming step S30B. Further, the second transport layer forming step S50 includes a second organic semiconductor layer forming step S50B and a second metal oxide layer forming step S50A. Accordingly, the solar cell 100 having the configuration shown in FIG. 2 can be manufactured.

In the first electrode forming step S20, the first electrode 23A is formed on the upper side of the transparent substrate 21. In the first metal oxide layer forming step S30A, the first metal oxide layer 27A is formed as the first transport layer 24A on the upper side of the first electrode 23A by the ion plating method. In the first organic semiconductor layer forming step S30B, the second layer 24Ab that is a first organic semiconductor layer is formed on the upper side of the first metal oxide layer 27A by coating, such as screen printing or spin coating, as the first transport layer 24A. In the photoelectric conversion layer forming step S40, the photoelectric conversion layer 22 is formed on the upper side of the second layer 24Ab, which is the first organic semiconductor layer, by coating, such as screen printing or spin coating. In the second organic semiconductor layer forming step S50B, a second layer 24Bb that is a second organic semiconductor layer is formed on the upper side of the photoelectric conversion layer 22 by coating, such as screen printing or spin coating, as the second transport layer 24B. In the second metal oxide layer forming step S50A, the second metal oxide layer 27B is formed as the second transport layer 24B on the upper side of the second layer 24Bb, which is the second organic semiconductor layer, by the ion plating method. In the second electrode forming step S60, the second electrode 23B is formed on the upper side of the second metal oxide layer 27B.

Next, the actions and effects of the manufacturing method for the solar cell 100, the manufacturing apparatus for the solar cell 100, and the solar cell 100 according to the present embodiment will be described.

First, a solar cell according to a comparative example will be described. An electron transport layer and a hole transport layer are often conductive, but often have performance close to insulation properties in order to have band adjustment and charge selectivity and are required to be formed to be thin. Further, pinholes should be reduced for the prevention of short circuits. Since a resistance value increases in a case where the electron transport layer or the hole transport layer is too thick, a current value to be extracted decreases. Since a resistance value decreases but pinholes are likely to be generated in a case where the electron transport layer or the hole transport layer is thin, a defect rate increases due to the occurrence of a short circuit.

In general, a transport layer is often made of TiO₂, and is formed by a method using a solution such as spin coating or screen printing, a method using physical vapor deposition such as sputtering or deposition, or a chemical vapor deposition method such as thermal CVD, plasma CVD, and ALD. In spin coating or screen printing, a precursor of TiO₂ is applied and then sintered to form the transport layer. However, there are problems in that the density of the sintered transport layer is low and pinholes are formed unless the transport layer is formed to have a thickness of 50 nm or more. Since a sintering temperature is relatively high at 200° C. to 500° C., a heat-resistant transparent substrate should be selected and it is difficult to use a general resin substrate. Further, a temperature of 200° C. to 500° C. is the heat-resistant temperature of general heat-resistant glass, and an even higher temperature is required as the sintering temperature of TiO₂.

In sputtering or the deposition, it is generally necessary to form a film having a thickness of 10 to 20 nm or more in order to form a pinhole-free film. In thermal CVD, plasma CVD, and ALD, a dense film can be formed, and a film having a thickness of 10 nm or less without pinholes can be formed. However, since many gases used in thermal CVD, plasma CVD, and ALD are harmful gases, there is a problem that an environmental load is high. That is, handling is difficult and devices should be installed, which causes an increase in production costs.

In contrast, in the manufacturing method for the solar cell 100 according to the present embodiment, in the transport layer forming steps S30 and S50 of forming the transport layers 24A and 24B, the metal oxide layers 27A and 27B are formed by an ion plating method using plasma containing oxygen. Since the electron transport layer or the hole transport layer is formed by an ion plating method which is a film forming method having a high coverage in this way, it is possible to reduce the resistance values of the transport layers 24A and 24B and to suppress defects caused by the generation of pinholes. Here, the plasma used for activation in the ion plating method is reactive plasma containing oxygen. Since the reactive plasma containing oxygen is used, it is possible to adjust the amount of oxygen loss from the transport layers 24A and 24B during the formation of a film. For this reason, it is possible to suppress the generation of pinholes in the transport layers 24A and 24B and to adjust a band within the range of the characteristics of a material. Accordingly, the performance and productivity of the solar cell 100 can be improved.

In the transport layer forming steps S30 and S50, plasma may be generated using the pressure gradient type plasma gun 7. In a case where the pressure gradient type plasma gun 7 is used, plasma can be stably generated.

In the transport layer forming steps S30 and S50, plasma may be guided to the film forming material Ma by the ring hearth 6 (magnetic field generating unit). In this case, since plasma can be smoothly guided to the film forming material Ma, the film forming material Ma can be caused to react with the plasma, so that productivity can be improved.

The photoelectric conversion layer 22 may contain an organic/inorganic semiconductor having a perovskite structure. The photoelectric conversion layer 22 may contain an organic semiconductor.

The manufacturing method for the solar cell 100 may include the first electrode forming step S20 of forming the first electrode 23A on the upper side of a resin substrate and the first transport layer forming step S30 of forming the metal oxide layer 27A on the upper side of the first electrode 23A with an ion plating method. In this case, since a film is formed by the ion plating method, it is possible to suppress damage to the resin substrate, which is an organic substance, caused by heat. Accordingly, a resin having low heat resistance can be adopted.

The manufacturing method for the solar cell 100 may include the first electrode forming step S20 of forming the first electrode 23A on the upper side of a glass substrate, the first transport layer forming step S30 of forming the first transport layer 24A for transporting one of the electrons and the holes on the upper side of the first electrode 23A, the photoelectric conversion layer forming step S40 of forming the photoelectric conversion layer 22 containing an organic substance on the upper side of the first transport layer 24A, the second metal oxide layer forming step S50A of forming the second metal oxide layer 27B as the second transport layer 24B for transporting the other of the electrons and the holes on the upper side of the photoelectric conversion layer 22 with an ion plating method, and the second electrode forming step S60 of forming the second electrode 23B on the upper side of the second metal oxide layer 27B. Since the glass substrate is resistant to heat, a film forming method that is performed at a high temperature can be adopted in the formation of each layer. On the other hand, after the photoelectric conversion layer 22 containing an organic substance susceptible to heat is formed, a film can be formed by an ion plating method to suppress damage to the photoelectric conversion layer 22, which contains the organic substance, caused by heat.

The manufacturing method for the solar cell 100 may include the first electrode forming step S20 of forming the first electrode 23A on the upper side of a substrate, the first metal oxide layer forming step S30A of forming the first metal oxide layer 27A on the upper side of the first electrode 23A with an ion plating method as the first transport layer 24A for transporting one of the electrons and the holes, the first organic semiconductor layer forming step S30B of forming the first organic semiconductor layer as the first transport layer 24A on the upper side of the first metal oxide layer 27A with coating, the photoelectric conversion layer forming step S40 of forming the photoelectric conversion layer 22 on the upper side of the first organic semiconductor layer with coating, the second organic semiconductor layer forming step S50B of forming the second organic semiconductor layer as the second transport layer 24B for transporting the other of the electrons and the holes on the upper side of the photoelectric conversion layer 22 with coating, the second metal oxide layer forming step S50A of forming the second metal oxide layer 27B as the second transport layer 24B on the upper side of the second organic semiconductor layer with an ion plating method, and the second electrode forming step S60 of forming the second electrode 23B on the upper side of the second metal oxide layer 27B. In this case, after the first metal oxide layer forming step S30A using the ion plating method is performed, the step of forming each layer with coating is performed until the second metal oxide layer forming step S50A using the ion plating method. The formation of a film using the ion plating method requires a vacuum environment, but the formation of a film using coating does not require a vacuum environment. For this reason, it is possible to smoothly perform coating without creating a vacuum environment in the first organic semiconductor layer forming step S30B, the photoelectric conversion layer forming step S40, and the second organic semiconductor layer forming step S50B. Deposition may be adopted instead of coating as methods of forming the first organic semiconductor layer, the photoelectric conversion layer, and the second organic semiconductor layer.

The manufacturing apparatus 150 for a solar cell manufactures the solar cell 100 including the photoelectric conversion layer 22 that absorbs light and converts the light into electrical energy, the electrodes 23A and 23B that extract the electrical energy generated in the photoelectric conversion layer 22, and the transport layers 24A and 24B that transport at least one of electrons and holes from the photoelectric conversion layer 22. The transport layer forming devices 152 and 154 for forming the transport layers 24A and 24B include the film forming devices 1 that form the metal oxide layers 27A and 27B with an ion plating method using plasma containing oxygen.

The part 200 for the manufacture of a solar cell is a part 200 for the manufacture of a solar cell used to manufacture the solar cell 100 including the photoelectric conversion layer 22 that absorbs light and converts the light into electrical energy, the electrodes 23A and 23B that extract the electrical energy generated in the photoelectric conversion layer 22, and the transport layers 24A and 24B that transport at least one of electrons and holes from the photoelectric conversion layer 22; and includes the plasma gun 7 that includes the cathode 60, the main hearth 17 which includes the main anode and in which the film forming material Ma can be disposed, and the ring hearth 6 (auxiliary hearth) that includes the auxiliary anode and is provided around the main hearth 17. The metal oxide layers 27A and 27B included in the transport layers 24A and 24B can be formed by an ion plating method using plasma, which contains oxygen and is generated between the plasma gun 7 and the main anode, in the film forming chamber 10b in which the part 200 for the manufacture of a solar cell is provided.

The solar cell 100 includes the photoelectric conversion layer 22 that absorbs light and converts the light into electrical energy, the electrodes 23A and 23B that extract the electrical energy generated in the photoelectric conversion layer 22, and the transport layers 24A and 24B that transport at least one of electrons and holes from the photoelectric conversion layer 22. The transport layers 24A and 24B include the metal oxide layers 27A and 27B that are formed by an ion plating method using plasma containing oxygen.

According to the manufacturing apparatus 150 for the solar cell 100 and the solar cell 100, it is possible to obtain the same actions and effects as those of the above-described manufacturing method for the solar cell 100.

The present disclosure is not limited to the above-mentioned embodiment.

The configurations of the solar cells shown in FIGS. 1A to 3 are merely examples, and the shape, thickness, and layer configuration thereof can be changed as appropriate.

It should be understood that the invention is not limited to the above-described embodiment, but may be modified into various forms on the basis of the spirit of the invention. Additionally, the modifications are included in the scope of the invention.

What is claimed is:

1. A manufacturing method for a solar cell including a photoelectric conversion layer that absorbs light and converts the light into electrical energy, an electrode that extracts the electrical energy generated in the photoelectric conversion layer, and a transport layer that transports electrons or holes from the photoelectric conversion layer, the manufacturing method comprising:
a transport layer forming step of forming the transport layer,
wherein, in the transport layer forming step, a metal oxide layer is formed by an ion plating method using plasma containing oxygen.

2. The manufacturing method for a solar cell according to claim 1,
wherein the plasma is generated using a pressure gradient type plasma gun, in the transport layer forming step.

3. The manufacturing method for a solar cell according to claim 1,
wherein the plasma is guided to a vaporized material using a magnetic field generating unit, in the transport layer forming step.

4. The manufacturing method for a solar cell according to claim 1,
wherein the photoelectric conversion layer contains an organic/inorganic semiconductor having a perovskite structure.

5. The manufacturing method for a solar cell according to claim 1,
wherein the photoelectric conversion layer contains an organic semiconductor.

6. The manufacturing method for a solar cell according to claim 1, further comprising:
an electrode forming step of forming the electrode on an upper side of a resin substrate; and
the transport layer forming step of forming the metal oxide layer on an upper side of the electrode with the ion plating method.

7. The manufacturing method for a solar cell according to claim 1, further comprising:
a first electrode forming step of forming a first electrode on an upper side of a glass substrate;
a first transport layer forming step of forming a first transport layer for transporting one of the electrons and the holes on an upper side of the first electrode;
a photoelectric conversion layer forming step of forming the photoelectric conversion layer containing an organic substance on an upper side of the first transport layer;
a metal oxide layer forming step of forming the metal oxide layer as a second transport layer for transporting the other of the electrons and the holes on an upper side of the photoelectric conversion layer with the ion plating method; and
a second electrode forming step of forming a second electrode on an upper side of the metal oxide layer.

8. The manufacturing method for a solar cell according to claim 1, further comprising:
a first electrode forming step of forming a first electrode on an upper side of a substrate;
a first metal oxide layer forming step of forming a first metal oxide layer as a first transport layer for transporting one of the electrons and the holes on an upper side of the first electrode with the ion plating method;
a first organic semiconductor layer forming step of forming a first organic semiconductor layer as the first transport layer on an upper side of the first metal oxide layer with coating;
a photoelectric conversion layer forming step of forming the photoelectric conversion layer on an upper side of the first organic semiconductor layer with coating;
a second organic semiconductor layer forming step of forming a second organic semiconductor layer as a second transport layer for transporting the other of the electrons and the holes on an upper side of the photoelectric conversion layer with coating;
a second metal oxide layer forming step of forming a second metal oxide layer as the second transport layer on an upper side of the second organic semiconductor layer with the ion plating method; and
a second electrode forming step of forming a second electrode on an upper side of the second metal oxide layer.

9. A manufacturing apparatus for a solar cell including a photoelectric conversion layer that absorbs light and converts the light into electrical energy, an electrode that extracts the electrical energy generated in the photoelectric conversion layer, and a transport layer that transports at least one of electrons and holes from the photoelectric conversion layer, the manufacturing apparatus comprising:
a transport layer forming device for forming the transport layer,
wherein the transport layer forming device includes a film forming device that forms a metal oxide layer with an ion plating method using plasma containing oxygen.

10. The manufacturing apparatus for a solar cell according to claim 9,
wherein the film forming device includes a vacuum chamber, a transport mechanism, and a film forming mechanism.

11. The manufacturing apparatus for a solar cell according to claim 10,
wherein the vacuum chamber is made of a conductive material and is connected to a ground potential.

12. The manufacturing apparatus for a solar cell according to claim 11,
wherein the vacuum chamber is a member in which an object is accommodated and film forming treatment is performed, and
the vacuum chamber includes a transport chamber in which the object on which a film made of a film forming material is to be formed is transported, a film forming chamber in which the film forming material is diffused, and a plasma port through which plasma emitted in a form of a beam from a pressure gradient type plasma gun is received to the vacuum chamber.

13. The manufacturing apparatus for a solar cell according to claim 12,
wherein the transport mechanism transports a substrate holding member, which holds the object in a state of facing the film forming material, in a transport direction, and includes a plurality of transport rollers installed in the transport chamber.

14. The manufacturing apparatus for a solar cell according to claim 13,
wherein the plurality of transport rollers are arranged at regular intervals in the transport direction, and transport the substrate holding member in the transport direction while supporting the substrate holding member.

15. The manufacturing apparatus for a solar cell according to claim 10,
wherein the film forming mechanism causes particles, which are generated as a result of sublimation of a film forming material, to adhere to an object using the ion plating method.

16. The manufacturing apparatus for a solar cell according to claim 15,
wherein the film forming mechanism includes a plasma gun, a steering coil, a hearth mechanism, and a ring hearth.

17. The manufacturing apparatus for a solar cell according to claim 16,
wherein a main body portion of the plasma gun is connected to a film forming chamber via a plasma port provided in a side wall of the film forming chamber, and the plasma gun generates plasma in the vacuum chamber.

18. The manufacturing apparatus for a solar cell according to claim 17,
wherein the steering coil is provided around the plasma port on which the plasma gun is mounted, and guides the plasma into a film forming chamber.

19. A part for manufacture of a solar cell used to manufacture a solar cell including a photoelectric conversion layer that absorbs light and converts the light into electrical energy, an electrode that extracts the electrical energy generated in the photoelectric conversion layer, and a transport layer that transports at least one of electrons and holes from the photoelectric conversion layer, the part comprising:
a plasma gun that includes a cathode;
a main hearth which includes a main anode and in which a film forming material is disposed; and
an auxiliary hearth that includes an auxiliary anode and is provided around the main hearth,
wherein a metal oxide layer included in the transport layer is formed by an ion plating method using plasma, which contains oxygen and is generated between the plasma gun and the main anode, in a film forming chamber in which the part for manufacture of a solar cell is provided.

20. A solar cell comprising:
a photoelectric conversion layer that absorbs light and converts the light into electrical energy;
an electrode that extracts the electrical energy generated in the photoelectric conversion layer; and
a transport layer that transports at least one of electrons and holes from the photoelectric conversion layer,
wherein the transport layer includes a metal oxide layer that is formed by an ion plating method using plasma containing oxygen.
